(19) United States
(12) Patent Application Publication
(10) Pub. No.: US 2025/0392296 A1
(43) Pub. Date: Dec. 25, 2025

(54) CIRCUIT AND METHOD FOR RECEIVER WITH TRACK PATH

(71) Applicant: Taiwan Semiconductor Manufacturing Company, Ltd., Hsinchu (TW)

(72) Inventors: Wen-Hung Huang, Hsinchu City (TW); Mu-Shan Lin, Hsinchu City (TW)

(73) Assignee: Taiwan Semiconductor Manufacturing Company, Ltd., Hsinchu (TW)

(21) Appl. No.: 18/753,738

(22) Filed: Jun. 25, 2024

(51) Int. Cl. H03K 5/14; G06F 1/08; G06F 1/12; H03K 3/017; H03K 5/00

(52) U.S. Cl. CPC H03K 5/14; G06F 1/08; G06F 1/12; H03K 3/017; H03K 2005/00078

(57) ABSTRACT

A circuit includes a first clock path configured to receive a first clock signal, and provide an adjusted version of the first clock signal with a first clock phase, a second clock path configured to receive a second clock signal, and provide an adjusted version of the second clock signal with a second clock phase related to the first clock phase, a data path configured to receive a data signal, and provide an adjusted version of the data signal with a third clock phase, and a track path configured to receive a third clock signal, and provide an adjusted version of the third clock signal with the first clock phase. The track path is substantially similar to the data path so as to mimic the third clock phase as the first clock phase.

### BACKGROUND

There are two types of 3D/2.5D integrated circuit (IC) interface. One type has fast speed per link with a complex circuit. For example, Universal Chiplet Interconnect Express (UCIe) interface can be in this type with up to 32 Gb/s data rate. The other type can have slower speed per link but with a simple circuit. The interfaces can include a receiver and a transmitter to communicate therebetween.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of an example circuit, in accordance with some embodiments.

FIG. 2 is a block diagram of an example circuit, in accordance with some embodiments.

FIG. 3 is a flow diagram of an example method for operating a circuit, in accordance with some embodiments.

FIG. 4 is a flow chart of an example method for operating a circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In an integrated circuit (IC) (e.g., 2.5D/3D) die-to-die interface, a clock (CLK) may not be synchronized. Each chiplet may independently deliver both transmitting data (TX DATA) and transmitting clock (TX CLK). The TX CLK can be generated locally, and the TX CLK may be unsynchronized with other chips' clock domains. Each chiplet may synchronize a receiving clock (RX CLK) with its local clock domain. To align/synchronize the clock, a complex circuit may need to be designed, which may not be cost effective and may have noise issues (e.g., a dynamic power noise jitter). For example, for a high speed die-to-die transceiver (e.g., with a data rate up to 32 Gbps), high accuracy quadrature phase clocks are needed. However, adding more data lanes could cause a clock tree distribution mismatch (e.g., Monte Carlo mismatch). Furthermore, the clock paths may experience delay variation during a voltage shift and temperature change. Therefore, there is a need for runtime recalibration for the voltage and temperature drift.

The present disclosure can synchronize clocking for the IC die-to-die interface with a cost effective and simple circuit design, while improving the noise issues (e.g., reducing the power noise jitter) and addressing the voltage and temperature drift. Incorporating the interface with a tracking circuit, the receiver lane-to-lane skew can be calibrated (e.g., reduced to be less than 0.5 ps). According to the present disclosure, the receiver circuit can include a track path configured to receive a tracking clock signal and provide an adjusted version of the tracking clock signal. The track path can be substantially similar to a data path so as to mimic the tracking clock phase as the clock phase of a clock signal of the receiver circuit. The techniques disclosed herein can solve the mismatch issues, including the Monte Carlo mismatch, while providing coarse tune resolution (e.g., 10 ps/0.32 UI) and fine tune resolution (e.g., 0.5 ps/0.016 UI). For example, the de-skew buffer resolution can be 0.5 ps/0.016 UI for 32 Gbps operation. Furthermore, the data eye sampling clock (45 degrees/135 degrees) phase can be adjusted through a training protocol to be center-aligned. In some embodiments, a runtime re-calibration can support on-the-fly adaptation against the long term voltage and/or temperature drift. For example, corrections for duty cycle, quadrature phase, sampling phase, delta code, etc. can be performed.

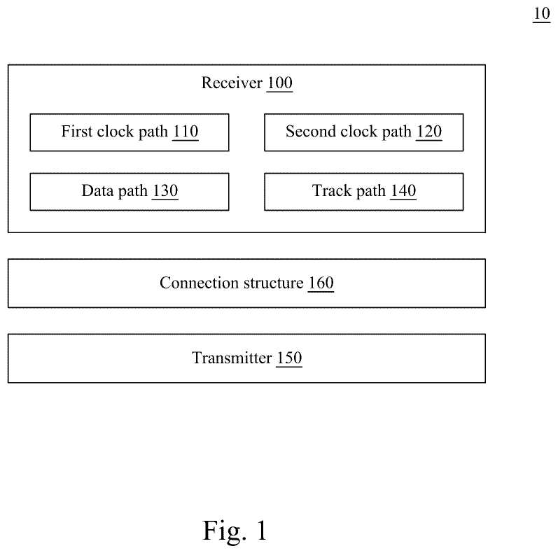

FIG. 1 is a block diagram of an example circuit 10, in accordance with some embodiments. The circuit 10 may be or include an IC die-to-die interface. For example, the circuit 10 may be a 3D or 2.5D IC interface. In some embodiments, the circuit 10 may be or include an Universal Chiplet Interconnect Express (UCIe) interface. The circuit 10 can be configured to interconnect chiplets (e.g., semiconductor dies, memory modules, etc.) or components within a chiplet, and facilitate communication therebetween. In some embodiments, the circuit 10 can include a receiver 100, a transmitter 150, and a connection structure 160. The receiver 100 can include a first clock path 110, a second clock path 120, a data path 130, and a track path 140. Shown in FIG. 1 is a non-limiting example of the circuit 10. In some embodiments, the circuit 10 can include more, fewer, or different components than shown in or described with respect to FIG. 1.

The receiver 100 may be or include a circuit or any component configured to receive data, commands, or other signals transmitted from another chiplet, another component within the same chiplet, a main controller, etc. In some embodiments, the receiver 100 can include circuitry or various circuit components for signal conditioning, amplification, equalization, clock and data process, decoding, etc. For example, the receiver 100 can include circuitry configured to recover the clock signal and data from the incoming data stream and synchronize with the transmitted signals to extract the transmitted information.

The transmitter 150 may be or include a circuit or any component configured to transmit data, commands, or other signals to another chiplet, another component within the same chiplet, a main controller, etc. In some embodiments, the transmitter 150 can include circuitry or various circuit components for data encoding, modulation, amplification, signal conditioning, etc.

The connection structure 160 can be configured to couple the receiver 100 and the transmitter 150. In some embodiments, the connection structure 160 can physically connect the receiver 100 and the transmitter 150 and can serve as electrical connection therebetween. In some embodiments, the connection structure 160 can be or include a plurality of bump structures. For example, the connection structure 160 can be or include solder balls (e.g., ball grid array (BGA)), copper pillars, stud bumps, controlled collapse chip connection (C4), etc.

The circuit 10 can be configured to calibrate clocking of the receiver 100, thereby synchronizing the same. In some embodiments, the receiver 100 can include the first clock path 110 configured to receive a first clock signal and provide an adjusted version of the first clock signal with a first clock phase. The receiver 100 can include the second clock path 120 configured to receive a second clock signal and provide an adjusted version of the second clock signal with a second clock phase related to the first clock phase. The receiver 100 can include the data path 130 configured to receive a data signal and provide an adjusted version of the data signal with a third clock phase. The receiver 100 can include the track path 140 configured to receive a third clock signal and provide an adjusted version of the third clock signal with the first clock phase. The track path 140 can be configured such that the track path 140 can be substantially similar to the data path 130 so as to mimic the third clock phase as the first clock phase. This can synchronize clocking for the circuit 10 while improving the noise issues (e.g., reducing the power noise jitter) and addressing the voltage and temperature drift. In addition, such mismatch issues as Monte Carlo mismatch, can be improved.

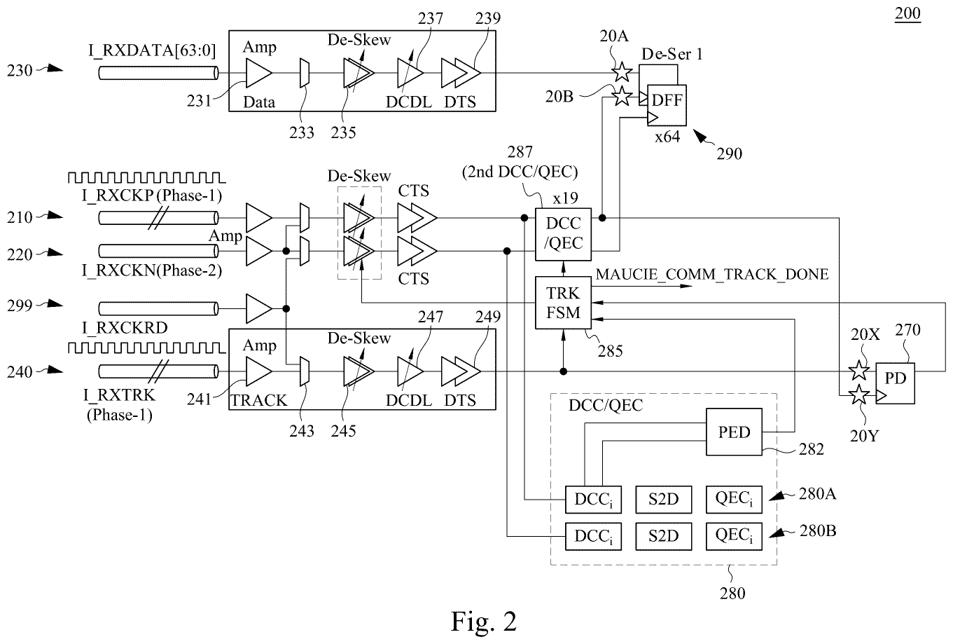

FIG. 2 is a block diagram of an example circuit 200, in accordance with some embodiments. In some embodiments, the circuit 200 may be substantially similar to or incorporate features of the receiver 100. The circuit 200 can include a first clock path 210, a second clock path 220, a data path 230, and a track path 240. In some embodiments, the first clock path 210, the second clock path 220, the data path 230, and the track path 240 may be substantially similar to or incorporate features of the first clock path 110, the second clock path 120, the data path 130, and the track path 140, respectively. Shown in FIG. 2 is a non-limiting example of the circuit 200. In some embodiments, the circuit 200 can include more, fewer, or different components than shown in or described with respect to FIG. 2.

In some embodiments, the first clock path 210 can be configured to receive a first clock signal I_RXCKP. The first clock path 210 can be configured to provide an adjusted version of the first clock signal I_RXCKP with a first clock phase (the adjust version of the first clock signal referred to as “RXCKP”). In some embodiments, the first clock path 210 can include am amplifier, a multiplexer, a de-skew, a clock tree synthesis (CTS), etc. The second clock path 220 can be configured to receive a second clock signal I_RXCKN. The second clock path 220 can be configured to provide an adjusted version of the second clock signal I_RXCKN with a second clock phase related to the first clock phase (the adjust version of the second clock signal referred to as “RXCKN”). In some embodiments, the second clock path 220 can include am amplifier, a multiplexer, a de-skew, a CTS, etc.

The data path 230 can be configured to receive a data signal I_RXDATA. The data path 230 can be configured to provide an adjusted version of the data signal I_RXDATA with a third clock phase (the adjust version of the data signal referred to as “RXDATA”). The track path 240 can be configured to receive a third clock signal I_RXTRK. In some embodiments, the data path 230 can be or include a harden macro under each a bump structure (e.g., the connection structure 160). In some embodiments, the data path 230 can include an amplifier 231, a multiplexer 233, one or more de-skew stages 235, a delay line circuit, such as a digital controlled delay line (DCDL) 237, a delay-tap shift (DTS) 239, and one or more buffers.

The track path 240 can be configured to provide an adjusted version of the third clock signal I_RXTRK with the first clock phase (the adjust version of the third clock signal referred to as “RXTRK”). In some embodiments, a difference between the first clock phase and the second clock phase can be adjusted to a predetermined value. For example, the difference between the first clock phase and the second clock phase can be 90 degrees in a quad data rate (QDR) mode. The difference between the first clock phase and the second clock phase can be 180 degrees in a double data rate (DDR) mode. In some embodiments, the track path 240 can include an amplifier 241, a multiplexer 243, one or more de-skew stages 245, a delay line circuit, such as a DCDL 247 and a DTS 249, and one or more buffers.

In some embodiments, the track path 240 can be configured such that the track path 240 can be substantially similar to the data path 230 so as to mimic the third clock phase as the first clock phase. In some embodiments, the track path 240 can be a “replica” of the data path 230. For example, the amplifier 241, the multiplexer 243, the one or more de-skew stages 245, the delay line circuit, such as the DCDL 247 and the DTS 249, and the one or more buffers can be substantially similar to or identical to the amplifier 231, the multiplexer 233, the one or more de-skew stages 235, the delay line circuit, such as the DCDL 237 and the DTS 239, and the one or more buffers of the data path 230.

In some embodiments, the DCDL 247 of the track path 240 can be configured to provide coarse tune resolution. In some embodiments, the track path 240 can be configured to provide fine tune resolution. In some embodiments, the track path 240 can be configured to provide the fine tune resolution as well as the coarse tune resolution. For example, the circuit 200 can perform a self-calibration from a coarse resolution (e.g., 10 ps) to a fine resolution (e.g., 0.5 ps) to provide a matched-delay quality. The circuit 200 can be configured to calibrate an initial clock phase by adjusting a de-skew stage (e.g., the one or more de-skew stages 245, etc.) and/or the one or more buffers (e.g., of the track path 240). The circuit 200 can be configured to calibrate an initial DCC/QEC digital control code.

In some embodiments, the circuit 200 can include a phase detector 270 configured to receive the adjusted version of the first clock signal RXCKP through the first clock path 210 and the adjusted version of the third clock signal RXTRK through the track path 240. In some embodiments, the phase detector 270 can be configured to determine whether the first clock phase and the third clock phase are in phase. For example, the phase detector 270 can determine the first clock phase in response to receiving the adjusted version of the first clock signal RXCKP, determine the third clock phase in response to receiving the adjusted version of the third clock signal RXTRK, and compare the first clock phase and the third clock phase. In some embodiments, the phase detector 270 can provide a result of the comparison to a finite state machine (TRK FSM) 285.

In some embodiments, the circuit 200 can include a first duty cycle corrector/quadrature error corrector (DCC/QEC) 280A and a second DCC/QEC 280B (collectively referred to as the DCC/QEC 280). The first DCC/QEC 280A can be configured to operatively couple with the first clock path 210, and the second DCC/QEC 280B can be configured to operatively couple with the second clock path 220. In some embodiments, the DCC/QEC 280 can include one or more sub-blocks. In some embodiments, the DCC/QEC 280 can include one or more DCC sub-blocks. The DCC sub-blocks can be configured to perform rising/falling time adjustment. In some embodiments, the DCC/QEC 280 can include one or more single-to-differential (S2D) sub-blocks. The S2D sub-block can be configured to perform S2D conversion. For example, the DCC/QEC 280 can be configured to generate a quadrature phase based on two S2D sub-blocks. In some embodiments, the DCC/QEC 280 can include one or more QEC sub-blocks. The QEC sub-block can be configured to perform quadrature phase adjustment.

In some embodiments, the DCC/QEC 280 can include a phase edge detection (PED) 282. The PED 282 can be configured to detect duty cycles and/or phases. The PED 282 can be configured to detect whether the duty cycles and/or the phases are aligned. In some embodiments, the PED 282 can be configured to detect whether the clock duty cycle is a certain number (e.g., 50%) during the DCC calibration and/or configured to detect the quadrature phase alignment during the QEC calibration. In some embodiments, the DCC/QEC 280 can provide a result of the detection to the TRK FSM 285.

In some embodiments, the circuit 200 can include the TRK FSM 285. The TRK FSM 285 can be operably coupled to the DCC/QEC 280 and the phase detector 270. In some embodiments, the TRK FSM 285 can be configured to adjust a clock rising/falling time for the DCC calibration and phase adjustment for the QEC calibration based on the detection result from the DCC/QEC 280. In some embodiments, the TRK FSM 285 can receive an input from the phase detector 270. For example, the TRK FSM 285 can receive an input including the phase alignment between the track path 240 and the first clock path 210 (and/or the second clock path 220). In some embodiments, the TRK FSM 285 can receive an operating clock from the track path 240 (e.g., when the track path 240 is active for power saving). In some embodiments, outputs from the DCC/QEC 280 can represent two clock phase outputs after the first clock path 210 and the second clock path 220 are calibrated with the DCC/QEC 280. The data path 230 can be configured to use the outputs from the DCC/QEC 280 as a data path slicer and/or D flip-flop sampling clock. In some embodiments, the clock phase relationship can remain in 90 degrees in the QDR mode. In some embodiments, the circuit 200 can include a second DCC/QEC 287. The second DCC/QEC 287 can be configured to receive an adjusted version of the clock signal from the TRK FSM 285 and provide to a de-serializer 290. In some embodiments, the second DCC/QEC 287 can be configured to provide clock duty and quadrature phase accuracy. The second DCC/QEC 287 can be configured to adjust the duty cycle of the clock signal (e.g., 50%) and/or adjust the phase of the clock signal (e.g., 90 degrees), thereby providing precise timing and phase alignment.

In some embodiments, the DCC/QEC 280 can be configured to serve as a replica of the second DCC/QEC 287. In some embodiments, the DCC/QEC 280 and the TRK FSM 285 can be configured to perform runtime recalibration of the second DCC/QEC. When the runtime recalibration is initiated, the TRK FSM 285 can be configured to calculate the delta recalibration code for the second DCC/QEC 287. In some embodiments, the delta recalibration code can be incrementally updated to the second DCC/QEC 287. In some embodiments, the delta recalibration code can be incrementally updated to the second DCC/QEC 287 without interrupting the normal data transmission.

In some embodiments, the circuit 200 can include a backup clock path 299. The backup clock path 299 can be configured to serve as a backup solution when any of the paths (e.g., the first clock path 210, the second clock path 220, etc.) has a failure. In some embodiments, the backup clock path 299 can serve as a clock repair path.

In some embodiments, the circuit 200 can include the de-serializer 290. For example, the circuit 200 can include at least one of the de-serializer 290 configured to receive the adjusted version of the data signal RXDATA and the clock signal adjusted based on the track path 240.

The circuit 200 can be configured to perform de-skep calibrations as discussed above, in various modes. In some embodiments, the circuit 200 can perform a cold boot de-skew self-calibration. The circuit 200 can perform the cold boot de-skew self-calibration during a cold booting of the circuit 200. During the cold boot calibration, the circuit 200 can be calibrated such that a duty cycle of the clock paths (e.g., the first clock path 210, the second clock path 220, etc.) can be calibrated to 50% and a quadrature phase thereof can be calibrated to 90 degrees. In some embodiments, a de-skew buffer of the clock paths (e.g., the first clock path 210 and/or the second clock path 220) can be calibrated for sampling phase alignment. After the cold boot de-skew self-calibration, the phases at a point 20X and a point 20Y can be in phase (e.g., the phase detector 270 can determine that the first clock phase and the third clock phase are in phase). It can be implied and/or ensured that the phases at a point 20A and a point 20B can be in phase, thereby providing in-phase signals to the de-serializer 290.

In some embodiments, the circuit 200 can perform a cold boot de-skew self-calibration during a training of the circuit 200. In some embodiments, the circuit 200 can be swept with a transmitter PI code (e.g., transmitter pre-emphasis settings) to get the aggregate data eye center (e.g., 64 data lanes). Then, the circuit 200 (e.g., a receiver per-lane de-skew buffer thereof) can be fine-tuned to remove mismatch (e.g., the Monte-Carlo mismatch). After the cold boot de-skew self-calibration during the training, the circuit 200 can be configured such that the sampling data (e.g., at the point 20A) and the clock phase (e.g., at the point 20B) can be center-aligned.

In some embodiments, the circuit 200 can perform a runtime re-calibration. In some embodiments, after the cold boot de-skew self-calibration, a code of the initial calibration can be recorded in the TRK FSM 285. In some embodiments, the circuit 200 can be re-calibrated based on the code of the initial calibration. For example, the DCC/QEC 280 (e.g., any sub-blocks thereof) can be re-calibrated. The DCC sub-blocks can be re-calibrated to address a voltage-temperature (V-T drift). In some embodiments, a DCC delta code can be calculated and applied to the DCC sub-blocks incrementally. The QEC sub-blocks can be re-calibrated to address the V-T drift. In some embodiments, a QEC delta code can be calculated and applied to the QEC sub-blocks incrementally. For example, a sampling clock can be re-calibrated to address the V-T drift. A CTS de-skew buffer code can be adjusted to re-calibrate the sampling clock.

In some embodiments, the runtime re-calibration can be performed during a normal operation of the circuit 200 (e.g., data transmission). During the runtime re-calibration, the circuit 200 can be calibrated such that the duty cycle of the clock paths can be re-calibrated to 50% and the quadrature phase of the clock paths can be re-calibrated to 90 degrees. In some embodiments, the de-skew buffer of the clock paths (e.g., the first clock path 210 and/or the second clock path 220) can be re-calibrated for sampling phase alignment. The delta codes (e.g., the DCC delta code, the QEC delta code, etc.) can be updated. After the runtime re-calibration, the clock quality and sampling phase quality can be maintained.

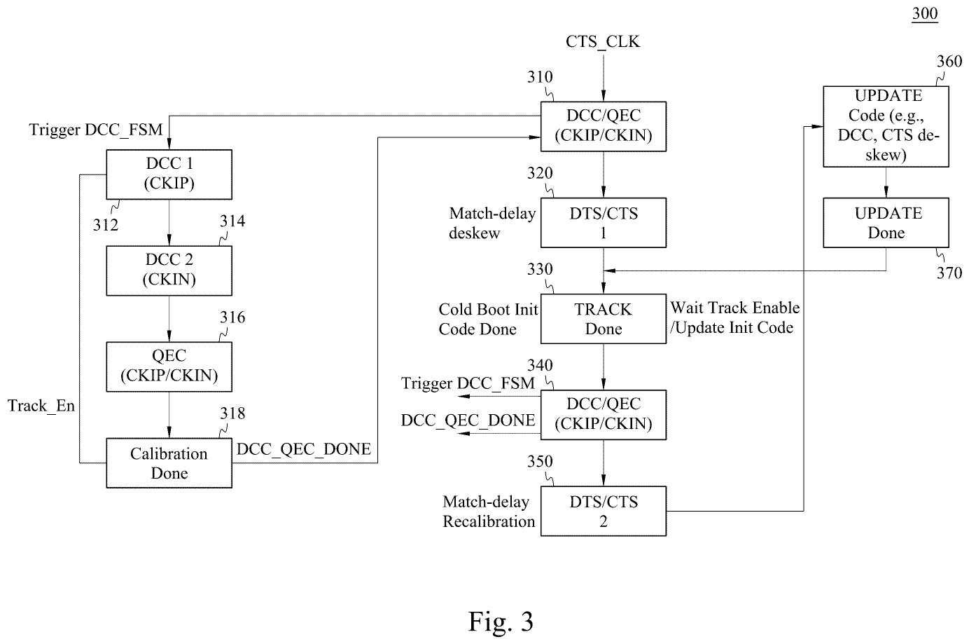

FIG. 3 is a flow diagram of an example method 300 for operating a circuit, in accordance with some embodiments. The method 300 may be performed by one or more components of the circuits 10, 100, 200, etc. In some embodiments, the method 300 can be performed by other entities. In some embodiments, the method 300 includes more, fewer, or different operations than shown in FIG. 3.

In a brief overview, the method 300 can start with operation 310 of performing a cold boot self-calibration. The method 300 can continue to operation 320 of de-skewing a match delay for the cold boot calibration. The method 300 can continue to operation 330 of completing the cold boot calibration. The method 300 can continue to operation 340 of performing a re-calibration. The method 300 can continue to operation 350 of de-skewing a match delay for the re-calibration. The method 300 can continue to operation 360 of updating a code. The method 300 can continue to operation 370 of completing the update.

At operation 310, a circuit (e.g., the circuit 200) can perform a cold boot self-calibration. The circuit can perform the cold boot de-skew self-calibration during a cold booting of the circuit based on a clock CTS_CLK. In some embodiments, the method 300, in performing the cold boot self-calibration at operation 310, can include triggering a DCC_FSM to calibrate a DCC/QEC block (e.g., the DCC/QEC 280). The method 300 can include operation 312 and operation 314 of calibrating duty cycles of the clock paths (e.g., the first clock path 210, the second clock path 220, etc.) to 50%. For example, a sub-block of the DCC/QEC block (e.g., the sub-blocks of the DCC/QEC 280 shown in FIG. 2) can adjust the duty cycle. The method 300 can include operation 316 of calibrating a quadrature phase of the clock paths to 90 degrees. For example, a sub-block of the DCC/QEC block (e.g., the sub-blocks of the DCC/QEC 280 shown in FIG. 2) can perform quadrature phase adjustment. In some embodiments, operation 314 and operation 316 can be omitted. For example, operation 314 and operation 316 can be omitted when the circuit is in the DDR mode. The method 300, in performing the cold boot self-calibration at operation 310, can continue to operation 318 of completing the cold boot self-calibration. In some embodiments, at operation 318, the method 300 can include continuing the calibration until a predetermine condition is met (e.g., 50% of the duty cycle, 90 degrees of the quadrature phase, etc.).

At operation 320, the circuit can de-skew a match delay based on the self-calibration performed at operation 310. At operation 330, the circuit can complete the cold boot self-calibration. In some embodiments, the method 300 can include recording and/or updating an initial code.

At operation 340, the circuit can perform a runtime re-calibration. In some embodiments, the circuit can perform the re-calibration similar to the cold boot self-calibration performed at operation 310. For example, the circuit can re-calibrate the DCC/QEC (e.g., the sub-blocks thereof) to address a voltage-temperature (V-T drift). In some embodiments, a DCC delta code can be calculated and applied to the DCC sub-blocks incrementally. The circuit can re-calibrate the QEC sub-blocks to address the V-T drift. In some embodiments, a QEC delta code can be calculated and applied to the QEC sub-blocks incrementally. For example, the circuit can adjust a CTS de-skew buffer code to re-calibrate a sampling clock and address the V-T drift. In some embodiments, at operation 340, the circuit can perform the re-calibration based on the code recorded and/or updated during the initial calibration (e.g., at operation 330).

In some embodiments, at operation 340, the circuit can perform the runtime re-calibration during a normal operation of the circuit (e.g., data transmission). The circuit can re-calibrate the duty cycle of the clock paths to 50% and the quadrature phase of the clock paths to 90 degrees.

At operation 350, the circuit can de-skew a match delay based on the re-calibration performed at operation 340. At operation 360, the circuit can update a code. In some embodiments, the circuit can update the DCC code. In some embodiments, the circuit can update the CTS de-skew code. In some embodiments, the circuit can update and/or record the delta codes (e.g., the DCC delta code, the QEC delta code, etc.). At operation 370, the circuit can complete the update. In some embodiments, the method 300 can return to operation 330, in which the circuit can wait for a Track Enable signal and can perform another re-calibration in response to receipt of the Track Enable signal.

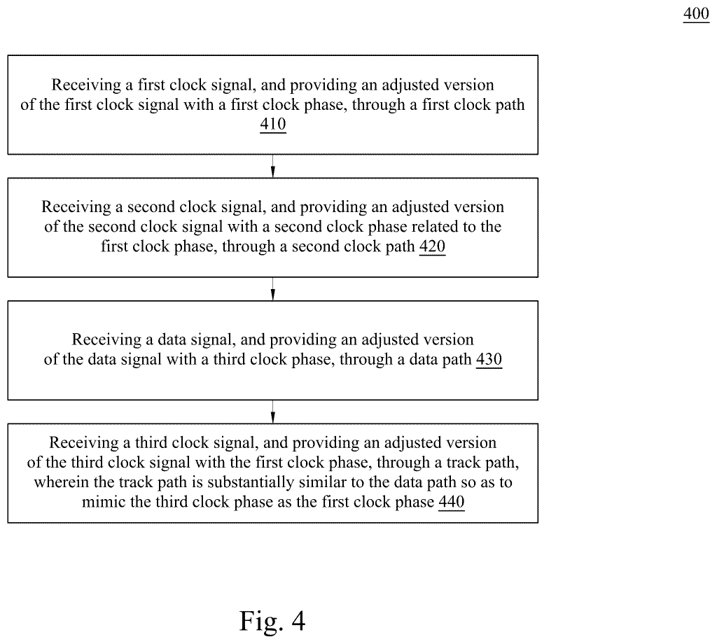

FIG. 4 is a flow chart of an example method 400 for operating a circuit, in accordance with some embodiments. The method 400 may be performed by one or more components of the circuits 10, 100, 200, etc. In some embodiments, the method 400 can be performed by other entities. In some embodiments, the method 400 includes more, fewer, or different operations than shown in FIG. 4.

In a brief overview, the method 400 can start with operation 410 of receiving a first clock signal and providing an adjusted version of the first clock signal with a first clock phase, through a first clock path. The method 400 can continue to operation 420 of receiving a second clock signal and providing an adjusted version of the second clock signal with a second clock phase related to the first clock phase, through a second clock path. The method 400 can continue to operation 430 of receiving a data signal and providing an adjusted version of the data signal with a third clock phase, through a data path. The method 400 can continue to operation 440 of receiving a third clock signal and providing an adjusted version of the third clock signal with the first clock phase, through a track path.

At operation 410, a first clock path (e.g., the first clock path 210) can receive a first clock signal (e.g., I_RXCKP shown in FIG. 2) and provide an adjusted version of the first clock signal (e.g., the RXCKP). At operation 420, a second clock path (e.g., the second clock path 220) can receive a second clock signal (e.g., I_RXCKN shown in FIG. 2) and provide an adjusted version of the second clock signal with a second clock phase related to the first clock phase. At operation 430, a data path (e.g., the data path 230) can receive a data signal (e.g., I_RXDATA shown in FIG. 2) and provide an adjusted version of the data signal with a third clock phase. At operation 440, a track path (e.g., the track path 240) can receive a third clock signal (e.g., I_RXTRK shown in FIG. 2) and can provide an adjusted version of the third clock signal with the first clock phase. In some embodiments, the track path can be substantially similar to the data path so as to mimic the third clock phase as the first clock phase. In some embodiments, a phase detector (e.g., the phase detector 270) can receive the adjusted version of the first clock signal through the first clock path and the adjusted version of the third clock signal through the track path. The phase detector can determine whether the first clock phase and the third clock phase are in phase.

In one aspect of the present disclosure, a circuit is disclosed. The circuit includes a first clock path configured to receive a first clock signal, and provide an adjusted version of the first clock signal with a first clock phase, a second clock path configured to receive a second clock signal, and provide an adjusted version of the second clock signal with a second clock phase related to the first clock phase, a data path configured to receive a data signal, and provide an adjusted version of the data signal with a third clock phase, and a track path configured to receive a third clock signal, and provide an adjusted version of the third clock signal with the first clock phase. The track path is substantially similar to the data path so as to mimic the third clock phase as the first clock phase.

In another aspect of the present disclosure, a circuit is disclosed. The circuit includes a receiver coupled to a transmitter through a plurality of connection structures. The receiver includes a first clock path configured to receive a first clock signal, and provide an adjusted version of the first clock signal with a first clock phase, a second clock path configured to receive a second clock signal, and provide an adjusted version of the second clock signal with a second clock phase related to the first clock phase, a data path configured to receive a data signal, and provide an adjusted version of the data signal with a third clock phase, and a track path configured to receive a third clock signal, and provide an adjusted version of the third clock signal with the first clock phase. The track path is substantially similar to the data path so as to mimic the third clock phase as the first clock phase.

In yet another aspect of the present disclosure, a method is disclosed. The method includes receiving a first clock signal and providing an adjusted version of the first clock signal with a first clock phase, through a first clock path, receiving a second clock signal and providing an adjusted version of the second clock signal with a second clock phase related to the first clock phase, through a second clock path, receiving a data signal and providing an adjusted version of the data signal with a third clock phase, through a data path, and receiving a third clock signal and providing an adjusted version of the third clock signal with the first clock phase, through a track path. The track path is substantially similar to the data path so as to mimic the third clock phase as the first clock phase.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., ±10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A circuit, comprising:
a first clock path configured to receive a first clock signal, and provide an adjusted version of the first clock signal with a first clock phase;
a second clock path configured to receive a second clock signal, and provide an adjusted version of the second clock signal with a second clock phase related to the first clock phase;
a data path configured to receive a data signal, and provide an adjusted version of the data signal with a third clock phase; and
a track path configured to receive a third clock signal, and provide an adjusted version of the third clock signal with the first clock phase;
wherein the track path is substantially similar to the data path so as to mimic the third clock phase as the first clock phase.

2. The circuit of claim 1, wherein a difference between the first clock phase and the second clock phase is 90 degrees.

3. The circuit of claim 1, wherein a difference between the first clock phase and the second clock phase is 180 degrees.

4. The circuit of claim 1, further comprising a phase detector configured to receive the adjusted version of the first clock signal through the first clock path, and the adjusted version of the third clock signal through the track path.

5. The circuit of claim 4, wherein the phase detector is further configured to determine whether the first clock phase and the third clock phase are in phase.

6. The circuit of claim 1, wherein the data path includes a first amplifier, a first multiplexer, one or more first de-skew stages, a first delay line circuit, and one or more first buffers.

7. The circuit of claim 6, wherein the track path includes a second amplifier, a second multiplexer, one or more second de-skew stages, a second delay line circuit, and one or more second buffers.

8. The circuit of claim 7, wherein the first amplifier is identical to the second amplifier, the first multiplexer is identical to the second multiplexer, the one or more first de-skew stages are identical to the one or more second de-skew stages, respectively, the first delay line circuit is identical to the second delay line circuit, and the one or more first buffers are identical to the one or more second buffers, respectively.

9. The circuit of claim 1, further comprising a first duty cycle corrector/quadrature error corrector (DCC/QEC) operatively coupled to the first clock path, and a second DCC/QEC operatively coupled to the second clock path.

10. The circuit of claim 1, further comprising at least one de-serializer configured to receive the adjusted version of the data signal and the adjusted version of the first clock signal.

11. A circuit, comprising:
a receiver coupled to a transmitter through a plurality of connection structures;
wherein the receiver includes:
a first clock path configured to receive a first clock signal, and provide an adjusted version of the first clock signal with a first clock phase;
a second clock path configured to receive a second clock signal, and provide an adjusted version of the second clock signal with a second clock phase related to the first clock phase;
a data path configured to receive a data signal, and provide an adjusted version of the data signal with a third clock phase; and
a track path configured to receive a third clock signal, and provide an adjusted version of the third clock signal with the first clock phase;
wherein the track path is substantially similar to the data path so as to mimic the third clock phase as the first clock phase.

12. The circuit of claim 11, wherein a difference between the first clock phase and the second clock phase is 90 degrees, and a difference between the first clock phase and the second clock phase is 180 degrees.

13. The circuit of claim 11, further comprising a phase detector configured to receive the adjusted version of the first clock signal through the first clock path, and the adjusted version of the third clock signal through the track path.

14. The circuit of claim 13, wherein the phase detector is further configured to determine whether the first clock phase and the third clock phase are in phase.

15. The circuit of claim 11, wherein the data path includes a first amplifier, a first multiplexer, one or more first de-skew stages, a first delay line circuit, and one or more first buffers, and wherein the track path includes a second amplifier, a second multiplexer, one or more second de-skew stages, a second delay line circuit, and one or more second buffers.

16. The circuit of claim 15, wherein the first amplifier is identical to the second amplifier, the first multiplexer is identical to the second multiplexer, the one or more first de-skew stages are identical to the one or more second de-skew stages, respectively, the first delay line circuit is identical to the second delay line circuit, and the one or more first buffers are identical to the one or more second buffers, respectively.

17. The circuit of claim 11, further comprising a first duty cycle corrector/quadrature error corrector (DCC/QEC) operatively coupled to the first clock path, and a second DCC/QEC operatively coupled to the second clock path.

18. The circuit of claim 11, further comprising at least one de-serializer configured to receive the adjusted version of the data signal and the adjusted version of the first clock signal.

19. A method, comprising:
receiving a first clock signal and providing an adjusted version of the first clock signal with a first clock phase, through a first clock path;
receiving a second clock signal and providing an adjusted version of the second clock signal with a second clock phase related to the first clock phase, through a second clock path;
receiving a data signal and providing an adjusted version of the data signal with a third clock phase, through a data path; and
receiving a third clock signal and providing an adjusted version of the third clock signal with the first clock phase, through a track path;
wherein the track path is substantially similar to the data path so as to mimic the third clock phase as the first clock phase.

20. The method of claim 19, further comprising:
receiving the adjusted version of the first clock signal through the first clock path, and the adjusted version of the third clock signal through the track path; and
determining whether the first clock phase and the third clock phase are in phase.
